(19) United States
(12) Patent Application Publication
(10) Pub. No.: US 2011/0309466 A1
(43) Pub. Date: Dec. 22, 2011

(54) SEMICONDUCTOR DEVICE AND METHOD FOR MANUFACTURING THE SAME

(75) Inventor: Hiroaki NANBA, Kanagawa (JP)

(73) Assignee: Renesas Electronics Corporation

(21) Appl. No.: 13/165,343

(22) Filed: Jun. 21, 2011

(30) Foreign Application Priority Data
Jun. 22, 2010 (JP) 2010-141336

(51) Int. Cl. H01L 27/06; H01L 21/784

(52) U.S. Cl. 257/503; 438/478; 257/E27.016; 257/E21.598

(57) ABSTRACT

The semiconductor device includes a first-conductivity-type region (an N-type well region, for example) and a first second-conductivity-type region (a P-type semiconductor substrate, for example) positioned to cover a lower surface of the first-conductivity-type region, a second second-conductivity-type region (a P-type well region, for example) that is positioned to surround the side faces of the first-conductivity-type region and is in contact with the first second-conductivity-type region, a guard ring that is electrically connected to the second second-conductivity-type region and is also electrically connected to a fixed potential terminal, an insulating film positioned to cover an upper surface of the first-conductivity-type region, and an analog element (a resistor element, for example) placed on the insulating film.

This application is based on Japanese patent application No. 2010-141336, the content of which is incorporated hereinto by reference.

### BACKGROUND

1. Technical Field

The present invention relates to a semiconductor device and a method for manufacturing the semiconductor device.

2. Related Art

In a semiconductor device (a high-frequency device) to which a high-frequency signal is to be input, the high-frequency signal that is input to an analog element such as a resistor element is sometimes transmitted to the substrate side due to capacitance coupling (capacitive coupling) with an insulating film located below the analog element. When the high-frequency signal is transmitted to the substrate side, the high-frequency signal being transmitted by the analog element attenuates, and as a result, the characteristics of the high-frequency device are degraded. Therefore, to stabilize the characteristics of the high-frequency device, attenuation of the high-frequency signal due to capacitance coupling should desirably be minimized as possible.

Japanese Laid-Open Patent Publication No. 2003-258217 discloses a semiconductor device in which a first island region that is electrically isolated is formed below a LOCOS film located below a resistor, and a P⁺-type isolation region connected to an anode electrode is formed below a device isolation region, to solve the problem of degradation of high-frequency characteristics due to parasitic capacitance between the resistor and the substrate. The first island region of this semiconductor device is an undoped region.

Japanese Laid-Open Patent Publication No. 2009-295867 discloses a semiconductor device that includes a semiconductor layer, an insulating film formed in the surface of the semiconductor layer, a resistor element that is formed on the insulating film, and a floating region that is formed at a portion in the semiconductor layer and is electrically in a floating state with respect to the surrounding area, the portion facing the resistor element, the insulating film being interposed between the portion and the resistor element. This semiconductor device further includes a first-conductivity-type semiconductor substrate that is provided in a lower layer of the semiconductor layer, and a first-conductivity-type isolation region that has a ring-like shape surrounding the floating region and is formed in the semiconductor layer. The floating region is of a second conductivity type. This semiconductor device further includes a guard ring that is formed into a ring-like shape corresponding to the shape of the isolation region, and faces the isolation region, with the insulating film being interposed between the isolation region and the guard ring. In the semiconductor device, the floating region is formed to improve the resistance to insulation breakdown. The guard ring is insulated from the isolation region through the insulating film.

### SUMMARY

The present inventor has recognized as follows. According to the technique disclosed in Japanese Laid-Open Patent Publication No. 2003-258217, it is difficult to sufficiently restrain attenuation of the high-frequency signal being transmitted by the analog element, and it is also difficult to sufficiently stabilize the characteristics of the semiconductor device.

In one embodiment, there is provided a semiconductor device including a first-conductivity-type region, a first second-conductivity-type region that is positioned to cover a lower surface of the first-conductivity-type region, a second second-conductivity-type region that is positioned to surround the side faces of the first-conductivity-type region, and is in contact with the first second-conductivity-type region, a guard ring that is electrically connected to the second second-conductivity-type region, and is electrically connected to a fixed potential terminal, an insulating film that is positioned to cover an upper surface of the first-conductivity-type region, and an analog element that is placed over the insulating film.

In this semiconductor device, the insulating film is provided below the analog element, and the first-conductivity-type region is provided below the insulating film. Here, the lower surface of the first-conductivity-type region is covered with the first second-conductivity-type region, and the side faces of the first-conductivity-type region are surrounded by the second second-conductivity-type region. Also, the upper surface of the first-conductivity-type region is covered with the insulating film. Accordingly, the first-conductivity-type region is electrically isolated, and is in a so-called floating state. Meanwhile, the first second-conductivity-type region and the second second-conductivity-type region are in contact with each other, and the second second-conductivity-type region is electrically connected to the fixed potential terminal through the guard ring.

In this semiconductor device, a capacitance is formed by the analog element and the first-conductivity-type region, with the insulating film being interposed therebetween. A junction capacitance is formed with the PN junction between the first-conductivity-type region and the first second-conductivity-type region, and the PN junction between the first-conductivity-type region and the second second-conductivity-type region. The capacitance between the analog element and the first-conductivity-type region and the junction capacitances are connected in series.

With the above described structure of the semiconductor device, the parasitic capacitance of the semiconductor device can be made smaller. Accordingly, the high-frequency signal to be transmitted by the analog element can be sufficiently prevented from attenuating due to parasitic capacitance. Thus, the characteristics of the semiconductor device can be made sufficiently stable.

In another embodiment, there is provided a method for manufacturing a semiconductor device, the method including forming a first-conductivity-type region that has a lower surface covered with a first second-conductivity-type region, forming a second second-conductivity-type region that surrounds the side faces of the first-conductivity-type region, and is in contact with the first second-conductivity-type region, forming a guard ring that is electrically connected to the second second-conductivity-type region, and is electrically connected to a fixed potential, forming an insulating film that covers the upper surface of the first-conductivity-type region, and forming an analog element over the insulating film.

According to the present invention, the high-frequency signal to be transmitted by an analog element can be sufficiently prevented from attenuating, and the characteristics of a semiconductor device can be sufficiently stabilized.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a schematic plan view of a semiconductor device according to a first embodiment;

FIG. 2 is a cross-sectional view of the semiconductor device, taken along the line A-A of FIG. 1;

FIG. 3 is a cross-sectional view of the semiconductor device, taken along the line B-B of FIG. 1;

FIG. 4 is a schematic cross-sectional view of the semiconductor device for explaining the advantageous effects of the first embodiment;

FIG. 5A is a schematic view for explaining the advantageous effects of the first embodiment, and FIG. 5A is a diagram showing the energy band at the PN junction in the semiconductor device;

FIG. 5B is a schematic view for explaining the advantageous effects of the first embodiment, and FIG. 5B is a diagram showing operations in which the potential difference at the PN junction in the semiconductor device is maintained;

FIG. 6 is a diagram illustrating the advantageous effects of the first embodiment;

FIG. 7 is a schematic plan view of a semiconductor device according to a second embodiment;

FIG. 8 is a cross-sectional view of the semiconductor device, taken along the line A-A of FIG. 7;

FIG. 9 is a schematic plan view of a semiconductor device according to a third embodiment;

FIG. 10 is a schematic plan view of a semiconductor device according to a fourth embodiment;

FIG. 11 is a schematic plan view of a semiconductor device according to a fifth embodiment;

FIG. 12A illustrates a semiconductor device according to a sixth embodiment, and FIG. 12A is a schematic plan view of the semiconductor device;

FIG. 12B illustrates a semiconductor device according to the sixth embodiment, and FIG. 12B is a cross-sectional view of the semiconductor device, taken along the line A-A of FIG. 12A;

FIG. 12C illustrates a semiconductor device according to the sixth embodiment, and FIG. 12C is a cross-sectional view of the semiconductor device, taken along the line B-B of FIG. 12A;

FIG. 13A illustrates a semiconductor device according to a comparative example, and FIG. 13A is a schematic plan view of the semiconductor device;

FIG. 13B illustrates a semiconductor device according to the comparative example, and FIG. 13B is a cross-sectional view of the semiconductor device, taken along the line A-A of FIG. 13A; and

FIG. 13C illustrates a semiconductor device according to the comparative example, and FIG. 13C is a cross-sectional view of the semiconductor device, taken along the line B-B of FIG. 13A.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes. Hereinafter, the embodiments of the present invention will be described as using the drawings. In all the drawings, like components are denoted by like reference numerals, and the same explanation will not be repeated in the specification.

[First Embodiment]

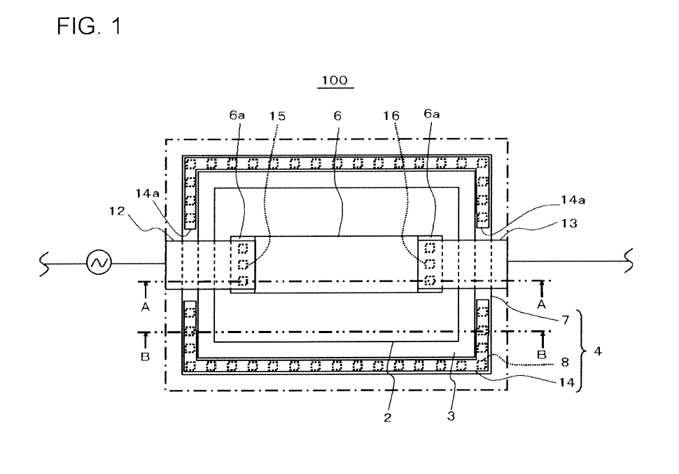

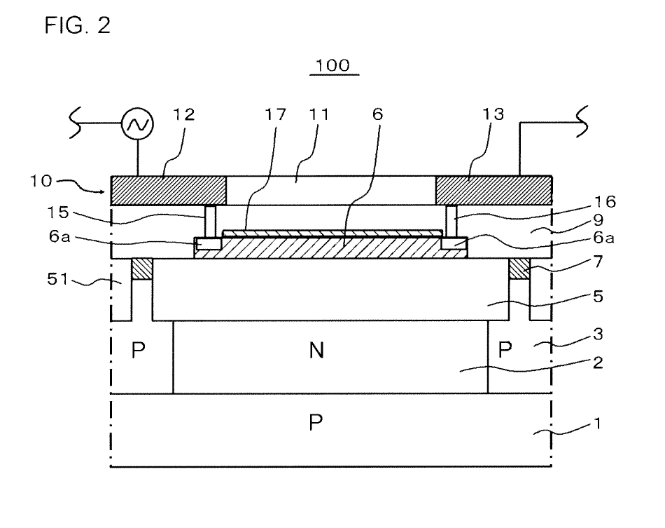

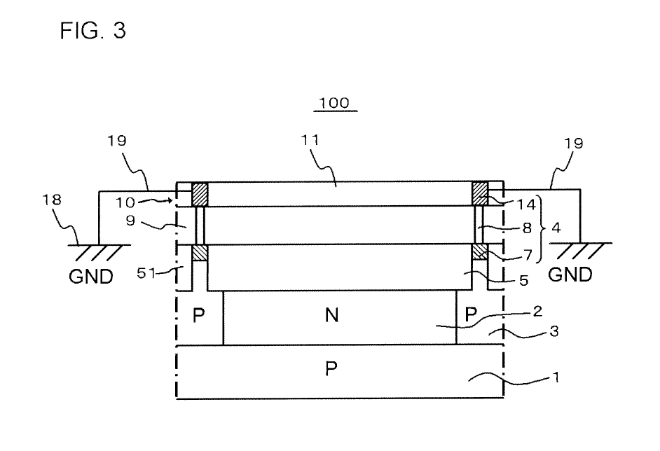

FIG. 1 is a schematic plan view of a semiconductor device 100 according to a first embodiment. FIG. 2 is a schematic cross-sectional view of the semiconductor device, taken along the line A-A of FIG. 1. FIG. 3 is a schematic cross-sectional view of the semiconductor device, taken along the line B-B of FIG. 1. In FIG. 1, an interlayer insulating film 9, an interconnect layer insulating film 11, a silicide block film 17, an insulating film 5, and an insulating film 51 are not shown.

The semiconductor device 100 according to this embodiment includes a first-conductivity-type region (an N-type well region 2, for example) and a first second-conductivity-type region (a P-type semiconductor substrate 1, for example) positioned to cover the lower surface of the first-conductivity-type region. The semiconductor device 100 further includes a second second-conductivity-type region (a P-type well region 3, for example) that is positioned to surround the side faces of the first-conductivity-type region and is in contact with the first second-conductivity-type region. The semiconductor device 100 further includes a guard ring 4 that is electrically connected to the second second-conductivity-type region and is also electrically connected to a fixed potential terminal, an insulating film 5 positioned to cover the upper surface of the first-conductivity-type region, and an analog element (a resistor element 6, for example) placed on the insulating film 5. In the following, this structure will be described in detail. The fixed potential terminal is a terminal connected to a fixed potential, and may be a ground terminal, for example.

The N-type well region 2 is formed in the surface layer of the P-type semiconductor substrate 1, for example. Accordingly, the lower surface of the N-type well region 2 is covered with a P-type region.

The P-type well region 3 is formed in the surface layer of the semiconductor substrate 1, and is positioned around the N-type well region 2, to surround the periphery of the N-type well region 2.

The insulating film 5 is placed on the N-type well region 2, to cover the upper surface of the N-type well region 2.

As described above, the N-type well region 2 has a lower surface surrounded by the P-type semiconductor substrate 1, has side faces surrounded by the P-type well region 3, and has an upper surface covered with the insulating film 5. Therefore, the N-type well region 2 is not electrically connected to any component, and is in a so-called floating state (or is electrically isolated).

The resistor element 6 is positioned to face the N-type well region 2, with the insulating film 5 being interposed therebetween. The resistor element 6 is made of polysilicon, for example. The conductivity type of the resistor element 6 is the same as the conductivity type of the P-type well region 3, which is the first conductivity type or the P⁺-type. However, the conductivity type of the resistor element 6 may be the second conductivity type (the N-type). Also, the resistor element 6 may be formed with a metal-containing film.

The resistor element 6 is formed into a long object extending in one direction along the surface of the semiconductor substrate 1, for example. More specifically, the planar shape of the resistor element 6 is a square shape (or a rectangle shape, to be more specific), for example.

As shown in FIG. 1, in the plan view, the visible outline of the N-type well region 2 is preferably located outside the visible outline of the resistor element 6. However, the visible outline of the N-type well region 2 may match the visible outline of the resistor element 6, or the visible outline of the N-type well region 2 may be located slightly inside the visible outline of the resistor element 6.

Also, in the plan view, the visible outline of the insulating film 5 is located outside the visible outline of the resistor element 6.

The P-type well region 3 surrounds the periphery of the N-type well region 2 in a ring-like manner (the planar shape being a rectangular ring-like shape, for example), and also surrounds the periphery of the insulating film 5 on the N-type well region 2.

In the semiconductor device 100, an insulating film 51 that is made of the same material as the insulating film 5 and has the same film thickness as the insulating film 5 is formed in a side located around the insulating film 5, with the P-type well region 3 being interposed therebetween, as shown in FIGS. 2 and 3.

Each of the insulating film 5 and the insulating film 51 is formed with a device isolating film having a Shallow Trench Isolation (STI) structure.

A high-concentration diffusion region of the first conductivity type (hereinafter referred to as the P⁺-diffusion region 7) that surrounds the N-type well region 2 in a ring-like manner (the planar shape being a rectangular ring-like shape, for example) is formed in the surface layer of the P-type well region 3. Unlike the later described conductor pattern 14, this P⁺-diffusion region 7 has a closed-loop shape as its planar shape. The P⁺-diffusion region 7 is electrically connected to the P-type well region 3 located therebelow, and is further electrically connected to the semiconductor substrate 1 through the P-type well region 3.

As shown in FIGS. 3 and 1, contact plugs (connecting members) 8 are formed on the P⁺-diffusion region 7, for example. Those contact plugs 8 are arranged in a ring-like manner in the direction in which the P⁺-diffusion region 7 extends. The lower end of each of the contact plugs 8 is in contact with the upper surface of the P⁺-diffusion region 7, and each of the contact plugs 8 is electrically connected to the P⁺-diffusion region 7.

The semiconductor device 100 includes a multilayer interconnect layer (only partially shown) including interlayer insulating films and interconnect layers that are alternately stacked. An interlayer insulating film 9 that is the first interlayer insulating film in the multilayer interconnect layer is formed on the P⁺-diffusion region 7, the insulating film 5, the insulating film 51, and the resistor element 6, and the contact plugs 8 are buried in the interlayer insulating film 9.

Further, an interconnect layer 10 that is the first interconnect layer in the above described multilayer interconnect layer is formed over the interlayer insulating film 9 and the contact plugs 8. The interconnect layer 10 includes first-layer interconnects (described later) formed with metal film, and an interconnect layer insulating film 11 that fills the spaces between those first-layer interconnects.

The first-layer interconnects include a pair of lead interconnects 12 and 13, a conductor pattern 14, and ground connecting lead interconnects 19.

Among those interconnects, the lead interconnect 12 is electrically connected to the resistor element 6 through contact plugs 15 formed on one end of the resistor element 6. That is, one end of the lead interconnect 12 is led to a location above the one end of the resistor element 6. The contact plugs 15 are provided between the one end of the resistor element 6 and the one end of the lead interconnect 12. The upper ends of the contact plugs 15 are in contact with the lead interconnect 12, and the lower ends of the contact plugs 15 are in contact with the resistor element 6.

Likewise, the lead interconnect 13 is electrically connected to the resistor element 6 through contact plugs 16 formed on the other end of the resistor element 6.

It should be noted that the contact plugs 15 and 16 are buried in the interlayer insulating film 9.

In the resistor element 6, the portions to which the contact plugs 15 and 16 are connected are silicided regions 6a. In the upper surface of the resistor element 6, the regions other than the silicided regions 6a are covered with a silicide block film 17.

The conductor pattern 14 faces the P⁺-diffusion region 7, with the respective contact plugs 8 being interposed therebetween. The upper ends of the respective contact plugs 8 are in contact with the lower surface of the conductor pattern 14. With this arrangement, the conductor pattern 14 is electrically connected to the P⁺-diffusion region 7 through the contact plugs 8.

As shown in FIG. 1, the conductor pattern 14 is formed to have the same ring-like planar shape as the P⁺-diffusion region 7. The conductor pattern 14 is placed in a position that overlaps with the position of the P⁺-diffusion region 7.

It should be noted that openings 14a for guiding the lead interconnects 12 and 13 located in the same layer level as the conductor pattern 14 to above the resistor element 6 are formed in the conductor pattern 14. That is, a pair of openings 14a for allowing the lead interconnects 12 and 13 to pass therethrough is formed in the conductor pattern 14. Therefore, unlike the P⁺-diffusion region 7, the conductor pattern 14 does not have a completely ring-like shape (a closed-loop shape), and is divided into two sections in this embodiment, for example.

In the above described structure, the P⁺-diffusion region 7, the respective contact plugs 8, and the conductor pattern 14 constitute the guard ring 4, for example.

With this guard ring 4, unnecessary inputs of external noise into the resistor element 6 are restrained, and variations in impedance of the resistor element 6 at high frequencies can be restrained. Where variations in the impedance at high frequencies are restrained, the impedance does not vary at high frequencies. More specifically, the reactance components in the resistor element 6 are sufficiently smaller than the resistance components in the resistor element 6.

The ground connecting lead interconnects 19 connect a fixed potential terminal 18 to the conductor pattern 14. Here, the fixed potential terminal 18 may be a terminal connected to the ground potential, for example. In the following description, the fixed potential terminal 18 will be referred to as the ground potential 18.

Although the planar arrangement of the ground connecting lead interconnects 19 is not shown in the drawings, the ground connecting lead interconnects 19 are connected to the conductor pattern 14 in such a manner as to extend radially from the conductor pattern 14, for example.

Although not shown in the drawings, an oscillator (not shown) that generates a high-frequency signal to be input to the resistor element 6 is provided in the vicinity of the resistor element 6 (or in the vicinity of the guard ring 4). The high-frequency signal generated from this oscillator is input to the resistor element 6 through the lead interconnect 12 and the contact plugs 15. An element (not shown) other than the resistor element 6 may be provided in a stage before the lead interconnect 12, and the high-frequency signal may be input to the resistor element 6 through that element. The resistor element 6 in turn outputs the high-frequency signal to the outside (another element, for example) through the contact plugs 16 and the lead interconnect 13. Here, the frequency of the high-frequency signal is preferably equal to or higher than 1 GHz (gigahertz), and specifically, is in the range of several GHz to several tens of GHz.

No elements other than the resistor element 6 are placed inside the guard ring 4. For example, a transistor (not shown) is surrounded by a different guard ring (not shown) from the guard ring 4, so that the resistor element 6 and the transistor do not coexist inside the guard ring 4. However, in a plan view, the number of resistor elements 6 surrounded by the guard ring 4 is not limited to one, and two or more resistor elements 6 may be surrounded by the guard ring 4, or a dummy resistor having the same structure as the resistor element 6 may be placed inside the guard ring 4, as will be described in other embodiments.

Since the semiconductor device 100 has the above structure, the semiconductor substrate 1 and the P-type well region 3 are electrically connected to the ground potential 18 through the P⁺-diffusion region 7, the contact plugs 8, the conductor pattern 14, and the ground connecting lead interconnects 19 in this order.

Next, a method for manufacturing the semiconductor device according to this embodiment is described.

The method for manufacturing the semiconductor device according to this embodiment includes the step of forming the first-conductivity-type region so that the lower surface of the first-conductivity-type region (the N-type well region 2, for example) is covered with the first second-conductivity-type region (the P-type semiconductor substrate 1, for example). This manufacturing method further includes the step of forming the second second-conductivity-type region (the P-type well region 3, for example) that surrounds the side faces of the first-conductivity-type region and is in contact with the first second-conductivity-type region. This manufacturing method further includes the step of forming the guard ring 4 that is electrically connected to the second second-conductivity-type region and is also electrically connected to the fixed potential. This manufacturing method further includes the step of forming the insulating film 5 that covers the upper surface of the first-conductivity-type region, and the step of forming the analog element (the resistor element 6, for example) on the insulating film 5. In the following, this method will be described in detail.

First, the P-type well region 3 is formed in the surface layer of the semiconductor substrate 1 of the first conductivity type (the P type, for example). To do so, a mask pattern (not shown) having an opening of a predetermined shape is first formed on the semiconductor substrate 1. With this mask pattern serving as a mask, P-type impurity ions (boron ions, for example) are injected into the surface layer of the semiconductor substrate 1 through the opening, to form the P-type well region 3. After that, the mask pattern is removed.

The N-type well region 2 is then formed in the surface layer of the semiconductor substrate 1. To do so, a mask pattern (not shown) having an opening of a predetermined shape is first formed on the semiconductor substrate 1. With this mask pattern serving as a mask, N-type impurity ions (phosphorus ions, for example) are injected into the surface layer of the semiconductor substrate 1 through the opening, to form the N-type well region 2. After that, the mask pattern is removed.

It should be noted that the region to be formed first may be either the N-type well region 2 or the P-type well region 3.

The insulating films 5 and 51 are then formed in the surface layer of the semiconductor substrate 1. To do so, a mask pattern (not shown) having an opening of a predetermined shape is formed on the semiconductor substrate 1. With this mask pattern serving as a mask, etching is performed on the surface layer of the semiconductor substrate 1 through the opening (the surface layers of the N-type well region 2 and the P-type well region 3 in this case), to form grooves in the surface layer of the semiconductor substrate 1. An oxide film (SiO₂) is then formed on the surface of the semiconductor substrate 1, to fill the grooves. The surface of the semiconductor substrate 1 is then polished, and the oxide film is left in the grooves. The portions of the oxide film located outside the grooves are removed from the semiconductor substrate 1, to form the insulating films 5 and 51.

A polysilicon film is then formed on the semiconductor substrate 1, and the polysilicon film is processed into the form of the resistor element 6. That is, a mask pattern (not shown) is first formed on the region to be the resistor element 6 in the polysilicon film. With this mask pattern serving as a mask, etching is performed to process the polysilicon film into the form of the resistor element 6. The mask pattern is then removed. Normally, in the step of forming the resistor element 6 in this manner, the gate of a transistor (not shown) is also formed.

A mask pattern (not shown) having an opening of a predetermined shape is then formed on the semiconductor substrate 1. With this mask pattern serving as a mask, P-type impurity ions (boron ions, for example) are injected into the surface layer of the semiconductor substrate 1 or the surface layer of the P-type well region 3 at a high concentration, to form the ring-like P⁺diffusion region 7.

The silicide block film 17 is then formed on the resistor element 6. The silicide block film 17 is formed to cover the regions other than the regions to be the silicided regions 6a in the resistor element 6. After a metal film is formed on the resistor element 6 by a sputtering technique or the like, a heat treatment is performed. By doing so, the metal that forms the metal film is caused to react with the polysilicon that forms the resistor element 6, and be silicided. In this manner, the silicided regions 6a are formed in both end portions of the resistor element 6. After that, the unreacted portions of the metal film are removed by using Sulfuric acid/hydrogen Peroxide Mixture (SPM) or the like.

The interlayer insulating film 9 is then formed on the resistor element 6 and the semiconductor substrate 1. In the interlayer insulating film 9, contact holes are then formed in the positions corresponding to the positions of the contact plugs 8, 15, and 16. The contact holes are then filled with metal. The portions of the metal protruding from the contact holes are removed by the Chemical Mechanical Polish (CMP) technique or the like, to form the contact plugs 8, 15, and 16.

The interconnect layer insulating film 11 is then formed on the interlayer insulating film 9. Interconnect grooves that correspond to the lead interconnects 12 and 13, the conductor pattern 14, and the ground connecting lead interconnects 19 are then formed in the interconnect layer insulating film 11. The interconnect grooves are then filled with a metal material (such as copper), and the portions of the metal material protruding from the interconnect grooves are removed by the Chemical Mechanical Polish (CMP) technique. In this manner, the lead interconnects 12 and 13, the conductor pattern 14, and the ground connecting lead interconnects 19 are formed in the interconnect layer insulating film 11, and the first-layer interconnect layer 10 can be formed.

After that, a necessary number of interlayer insulating films and a necessary number of interconnect layers (none of which is shown in the drawings) are alternately formed over the interconnect layer 10. In this manner, a multilayer interconnect can be formed.

Thus, the semiconductor device 100 is manufactured.

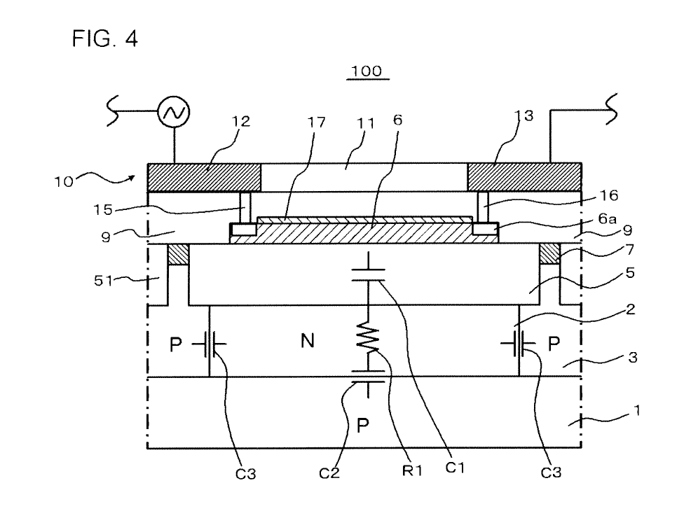

FIG. 4 is a diagram for explaining the advantageous effects of the first embodiment, and schematically shows a cross-section of the semiconductor device 100.

As shown in FIG. 4, in the semiconductor device 100, a capacitance C1 is equivalently formed by the resistor element 6 and the N-type well region 2, with the insulating film 5 being interposed therebetween. Meanwhile, a junction capacitance C2 is equivalently formed by a PN junction between the N-type well region 2 and the semiconductor substrate 1. Likewise, a junction capacitance C3 is equivalently formed by a PN junction between the N-type well region 2 and the P-type well region 3 surrounding the N-type well region 2. p The capacitance C1 and the junction capacitance C2 are connected in series to each other (with a resistance R1 being formed with the N-type well region 2 and being interposed therebetween, for example), as shown in FIG. 4. Likewise, the capacitance C1 and the junction capacitance C3 are connected in series to each other.

As described above, the capacitance C1 and the junction capacitance C2 are connected in series to each other, and the capacitance C1 and the junction capacitance C3 are connected in series to each other. With this arrangement, the parasitic capacitance formed in the semiconductor device 100 is smaller than that in the later described comparative example. Accordingly, the high-frequency signal transmitted by the resistor element 6 can be prevented from attenuating due to parasitic capacitance. In this manner, the characteristics of the semiconductor device 100 can be stabilized.

Since the semiconductor substrate land the P-type well region 3 are electrically connected to the ground potential 18 through the guard ring 4, the noise of the high-frequency signal can be shielded by the semiconductor substrate 1 and the P-type well region 3.

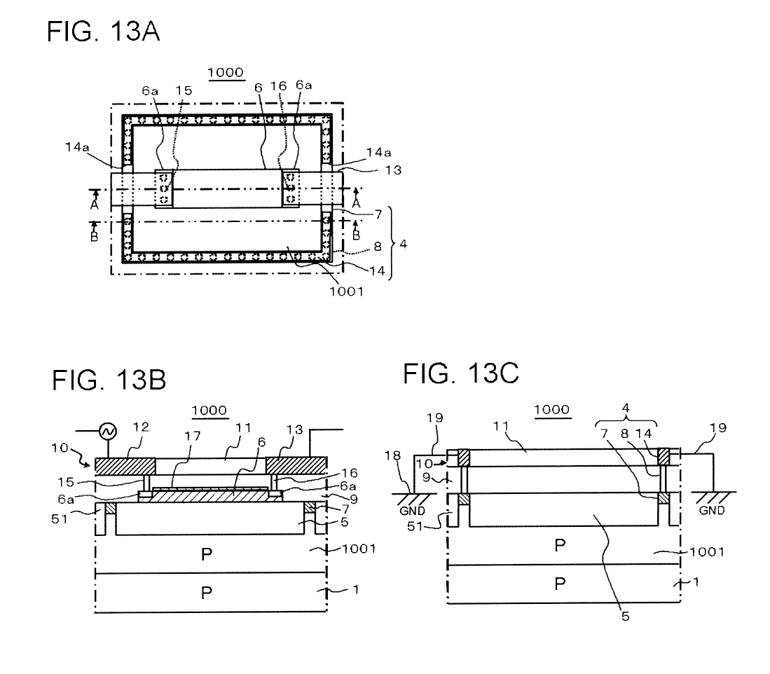

FIGS. 13A through 13C illustrate a semiconductor device 1000 according to a comparative example. FIG. 13A is a schematic plan view of the semiconductor device 1000. FIG. 13B is a cross-sectional view of the semiconductor device 1000, taken along the line A-A of FIG. 13A. FIG. 13C is a cross-sectional view of the semiconductor device 1000, taken along the line B-B of FIG. 13A.

The semiconductor device 1000 of the comparative example differs from the semiconductor device 100 according to the first embodiment only in the aspects described below, and the other aspects are the same as those of the semiconductor device 100.

The semiconductor device 1000 includes a P-type well region 1001, instead of the N-type well region 2 and the P-type well region 3. The shape of the P-type well region 1001 is the same as the combined shape of the N-type well region 2 and the P-type well region 3.

That is, instead of the N-type well region 2, the P-type well region 1001 exists below the resistor element 6, and the P-type well region 1001 is electrically connected to the ground potential 18 through the guard ring 4.

Accordingly, in the semiconductor device 1000 of the comparative example, the high-frequency signal transmitted by the resistor element 6 is more easily transmitted to the guard ring 4 through the insulating film 5 and the P-type well region 1001 due to capacitance coupling. This is because the P-type well region 1001 existing below the resistor element 6 is electrically connected to the guard ring 4. To counter this problem, the guard ring 4 and the P-type well region 1001 may not be electrically connected to each other. In that case, however, the noise of the high-frequency signal cannot be shielded by the P-type well region 1001.

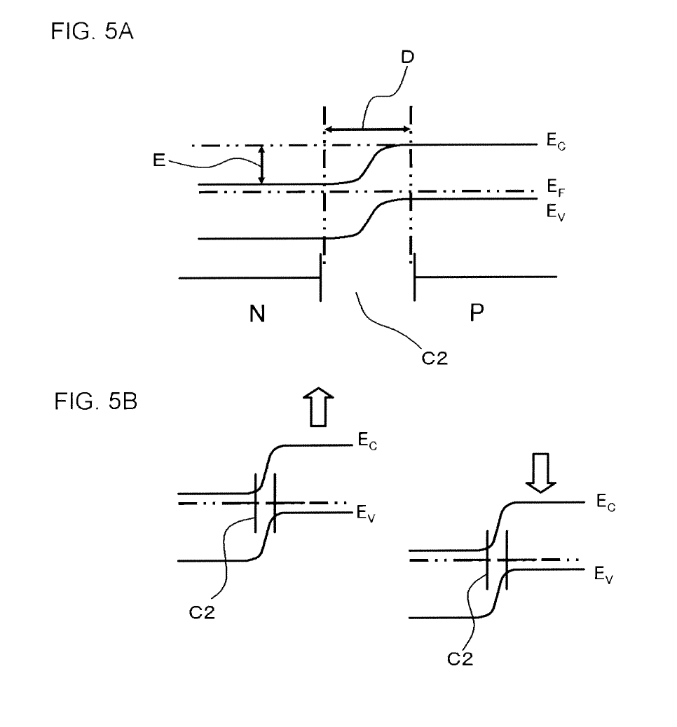

Referring now to FIG. 4 and FIGS. 5A and 5B, the advantageous effects of the first embodiment are described further.

FIGS. 5A and 5B are schematic views for explaining the advantageous effects of the first embodiment. FIG. 5A is a diagram showing the energy band at the PN junction in the semiconductor device. FIG. 5B is a diagram showing operations in which the potential difference at the PN junction in the semiconductor device is maintained.

FIG. 5A illustrates the energy band at the PN junction formed between the P-type semiconductor substrate 1 and the N-type well region 2. The range denoted by D in FIG. 5A is the range over which a depletion layer spreads, and the inner potential difference (or the built-in potential) is denoted by E.

Here, the N-side at the PN junction or the N-type well region 2 is in a floating state as described above. Therefore, when the potential of the P-side or the semiconductor substrate 1 varies, the potential of the N-type well region 2 also varies with (or varies substantially with) the variation, as shown in FIG. 5B. The left half of FIG. 5B illustrates an operation in which the potential of the N-type well region 2 becomes higher, varying with (or varying substantially with) an increase in the potential of the semiconductor substrate 1. Likewise, the right half of FIG. 5B illustrates an operation in which the potential of the N-type well region 2 becomes lower, varying with (or varying substantially with) a decrease in the potential of the semiconductor substrate 1. As a result, the junction capacitance C2 between the semiconductor substrate 1 and the N-type well region 2 is maintained at an almost constant value. It should be noted that the size of the junction capacitance C2 is inversely proportional to the square root of the built-in potential.

Likewise, at the PN junction formed between the P-type well region 3 and the N-type well region 2, the potential of the N-type well region 2 also varies with (or varies substantially with) the variation in the potential in the P-type well region 3. As a result, the junction capacitance C3 between the P-type well region 3 and the N-type well region 2 is also maintained at an almost constant value. The size of the junction capacitance C3 is also inversely proportional to the square root of the built-in potential.

As described above, in the semiconductor device 100, each of the junction capacitances C2 and C3 is maintained at an almost constant value. Accordingly, the high-frequency characteristics are stabilized.

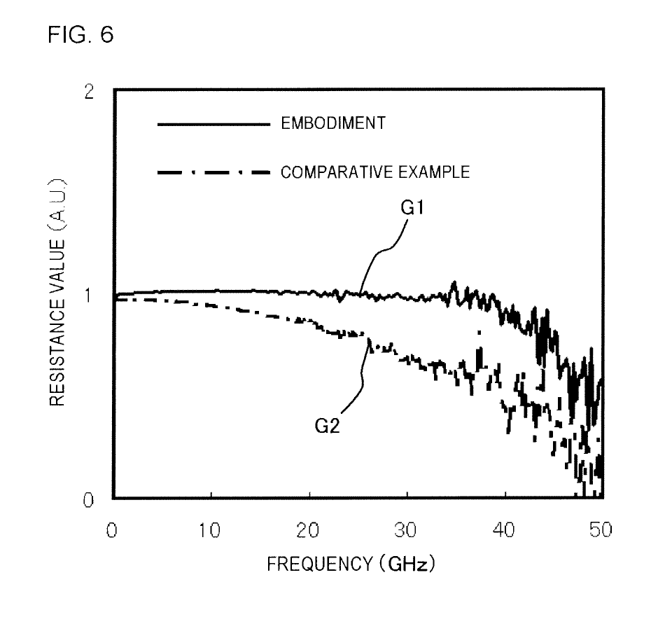

FIG. 6 is a diagram illustrating the advantageous effects of the first embodiment.

In FIG. 6, the abscissa axis indicates the frequency of the high-frequency signal to be input to the resistor element 6, and the ordinate axis indicates the resistance value (the unit being an arbitrary unit (A.U.) of the resistor element 6. In FIG. 6, the graph G1 represented by a solid line indicates the measurement data obtained with the semiconductor device 100 according to the first embodiment, and the graph G2 represented by a dot-and-dash line indicates the measurement data obtained with the semiconductor device 1000 according to the comparative example.

As can be seen from FIG. 6, in the case of the semiconductor device 1000 according to the comparative example, the resistance value of the resistor element 6 becomes remarkably lower as the frequency becomes higher.

In the semiconductor device 100 according to the first embodiment, on the other hand, the resistance value of the resistor element 6 is almost constant at frequencies of 34 GHz or lower, for example. That is, the resistance value of the resistor element 6 is prevented from deviating from a desired value.

In the semiconductor device 100 according to the first embodiment described above, the insulating film 5 is placed below the resistor element 6, and the N-type well region 2 is placed below the insulating film 5. The lower surface of the N-type well region 2 is covered with the P-type semiconductor substrate 1, and the side faces of the N-type well region 2 are surrounded by the P type well region Also, the upper surface of the N-type well region 2 is covered with the insulating film 5. Accordingly, the N-type well region 2 is electrically isolated, and is in a so-called floating state. On the other hand, the P-type semiconductor substrate 1 and the P-type well region 3 are in contact with each other, and the P-type well region 3 is electrically connected to the ground potential through the guard ring 4.

Since the semiconductor device 100 has the above described structure, the capacitance C1 is formed by the resistor element 6 and the N-type well region 2, with the insulating film 5 being interposed therebetween. Also, the junction capacitances C2 and C3 are formed by the PN junction between the semiconductor substrate 1 and the N-type well region 2, and the PN junction between the P-type well region 3 and the N-type well region 2. Furthermore, the capacitance C1 and the junction capacitance C2 are connected in series to each other, and the capacitance C1 and the junction capacitance C3 are connected in series to each other.

With this structure according to this embodiment, the parasitic capacitance of the semiconductor device 100 can be made smaller. Accordingly, the high-frequency signal to be transmitted by the resistor element 6 can be sufficiently prevented from attenuating due to parasitic capacitance. Thus, the characteristics of the semiconductor device 100 can be made sufficiently stable. For example, in a case where the analog element is the resistor element 6 as in this embodiment, the resistance value of the resistor element 6 can be prevented from deviating from a desired value.

Since the N-type well region 2 is electrically isolated and is in a floating state, the potential of the N-type well region 2 varies with the variation in the potential of the surrounding area. Therefore, the junction capacitances C2 and C3 formed by PN junctions are substantially maintained at the capacitances corresponding to the built-in potential. In this aspect, the characteristics of the semiconductor device 100 can also be stabilized.

In a plan view, the visible outline of the N-type well region 2 is located outside the visible outline of the resistor element 6. Accordingly, the high-frequency signal can be more suitably prevented from attenuating due to parasitic capacitance.

The semiconductor device 100 includes a multilayer interconnect, and the guard ring 4 is designed to include the P⁺-diffusion region 7 located in a lower position than the resistor element 6, the contact plugs 8, and the conductor pattern 14 located in a higher position than the resistor element 6. With this arrangement, the resistor element 6 can be efficiently shielded from external noise, and noise emission from the resistor element 6 to outside.

The first-layer interconnect layer 10 includes the lead interconnects 12 and 13 connected to the resistor element 6, and the openings 14a for allowing the lead interconnects 12 and 13 to pass therethrough are formed in the conductor pattern 14. With this arrangement, the conductor pattern 14 and the lead interconnects 12 and 13 can be formed in the same layer, and restrictions on the layout can be reduced.

[Second Embodiment]

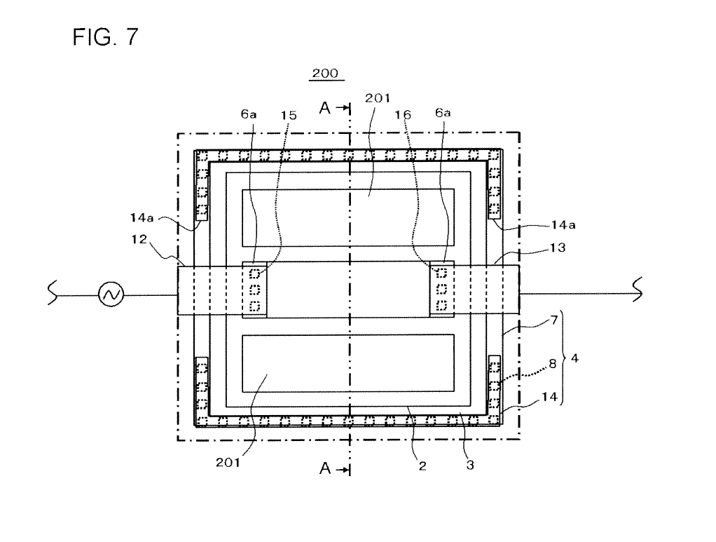

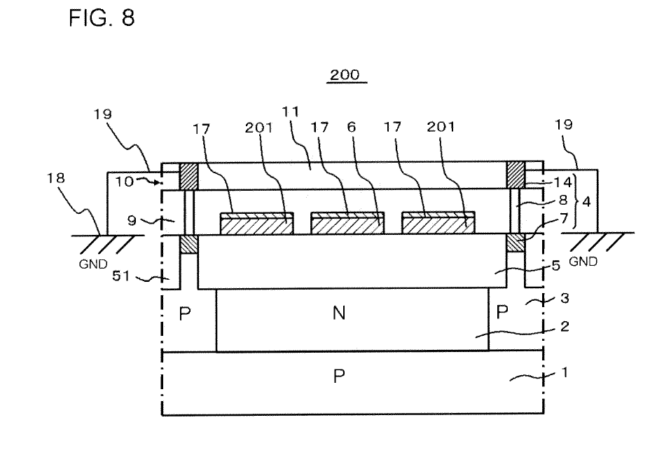

FIG. 7 is a plan view of a semiconductor device 200 according to a second embodiment. FIG. 8 is a schematic cross-sectional view of the semiconductor device 200, taken along the line A-A of FIG. 7. In FIG. 7, the interlayer insulating film 9, the interconnect layer insulating film 11, the silicide block film 17, the insulating film 5, and the insulating film 51 are not shown.

The semiconductor device 200 according to the second embodiment differs from the semiconductor device 100 according to the first embodiment only in the aspects described below, and the other aspects are the same as those of the semiconductor device 100.

As shown in FIGS. 7 and 8, in this embodiment, a dummy resistor 201 is provided on either side of the resistor element 6, and the resistor element 6 and the dummy resistors 201 are placed inside the guard ring 4.

Each of the dummy resistors 201 differs from the resistor element 6 only in not including the silicide regions 6a, and the other aspects of each of the dummy resistors 201 are the same as those of the resistor element 6. That is, the dummy resistors 201 are made of Pt-type polysilicon, for example.

The resistor element 6 and the dummy resistors 201 are arranged in parallel with one another. That is, each of the dummy resistors 201 is positioned so that the longitudinal direction of each of the dummy resistors 201 becomes parallel to the longitudinal direction of the resistor element 6. Also, the positions of both ends of the resistor element 6 are aligned with the positions of both ends of each of the dummy resistors 201. For example, the interval (the distance) between the resistor element 6 and one of the dummy resistors 201 is the same as the interval (the distance) between the resistor 6 and the other one of the dummy resistors 201.

The contact plugs 15 and 16 are not formed on the respective dummy resistors 201, and the lead interconnects 12 and 13 are not led to above the respective dummy resistors 201. The upper surface of each of the dummy resistors 201 is covered with the silicide block film 17, except for a portion on either end. Alternatively, the entire upper surface of each of the dummy resistors 201 is covered with a silicide block film 17.

In this embodiment, in a plan view, not only the resistor element 6 but also the respective dummy resistors 201 are preferably placed inside the visible outline of the N-type well region 2.

Also, in a plan view, not only the resistor element 6 but also the respective dummy resistors 201 are located inside the visible outline of the insulating film 5.

According to the second embodiment described above, the same advantageous effects as those of the first embodiment can be achieved. Also, since the dummy resistors 201 are positioned on both sides of the resistor element 6, uniform etching is performed on the resistor element 6 during the processing of the resistor element 6. Accordingly, the entire resistor element 6 can be formed into a flat shape with high precision.

[Third Embodiment]

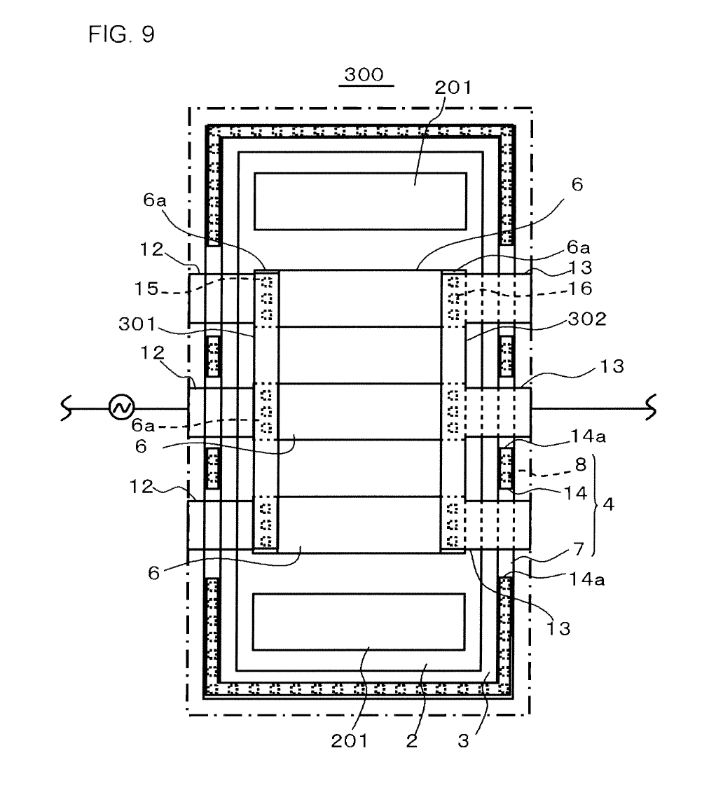

FIG. 9 is a plan view of a semiconductor device 300 according to a third embodiment. In FIG. 9, the interlayer insulating film 9, the interconnect layer insulating film 11, the silicide block film 17, the insulating film 5, and the insulating film 51 are not shown.

The semiconductor device 300 according to the third embodiment differs from the semiconductor device 200 according to the second embodiment only in the aspects described below, and the other aspects are the same as those of the semiconductor device 200.

As shown in FIG. 9, in this embodiment, resistor elements 6 (three resistor elements 6, for example) are arranged in parallel with one another. A dummy resistor 201 is placed on either outer end of the resistor elements 6. The resistor elements 6 and the dummy resistors 201 are placed inside the guard ring 4. The respective resistor elements 6 are arranged at regular intervals. The distance between each two adjacent resistor elements 6 is the same as the distance between each dummy resistor 201 and the adjacent resistor element 6.

The contact plugs 15 and 16 are formed on the respective resistor elements 6, and the lead interconnects 12 and 13 are led to above the respective resistor elements 6. Both end portions of each of the resistor elements 6 are connected to the corresponding lead interconnects 12 and 13 through the corresponding contact plugs 15 and 16. In each of the resistor elements 6, the regions to which the contact plugs 15 and 16 are connected are the silicided regions 6a, and the portions of the upper surface of each of the resistor elements 6 other than the silicided regions 6a are covered with a silicide block film 17.

Each two adjacent lead interconnects 12 are electrically connected to each other through a connecting interconnect 301 in the same layer as those lead interconnects 12. Likewise, each two adjacent lead interconnects 13 are electrically connected to each other through a connecting interconnect 302 in the same layer as those lead interconnects 13.

The high-frequency signal is input to the resistor elements 6 through one of the lead interconnects 12, for example.

In this embodiment, the conductor pattern 14 is divided into six sections, for example, and the lead interconnect 12 or 13 is inserted through the openings 14a formed between the divided sections of the conductor pattern 14. The divided sections of the conductor pattern 14 are located between adjacent lead interconnects 12 and between adjacent lead interconnects 13, respectively. Those divided sections are also electrically connected to the Pr-diffusion region 7 through the contact plugs 8.

In a plan view, the respective resistor elements 6 and the respective dummy resistors 201 are preferably placed inside the visible outline of the N-type well region 2.

Also, in a plan view, the resistor elements 6 and the respective dummy resistors 201 are located inside the visible outline of the insulating film 5.

According to the third embodiment described above, the same advantageous effects as those of the second embodiment can be achieved.

[Fourth Embodiment]

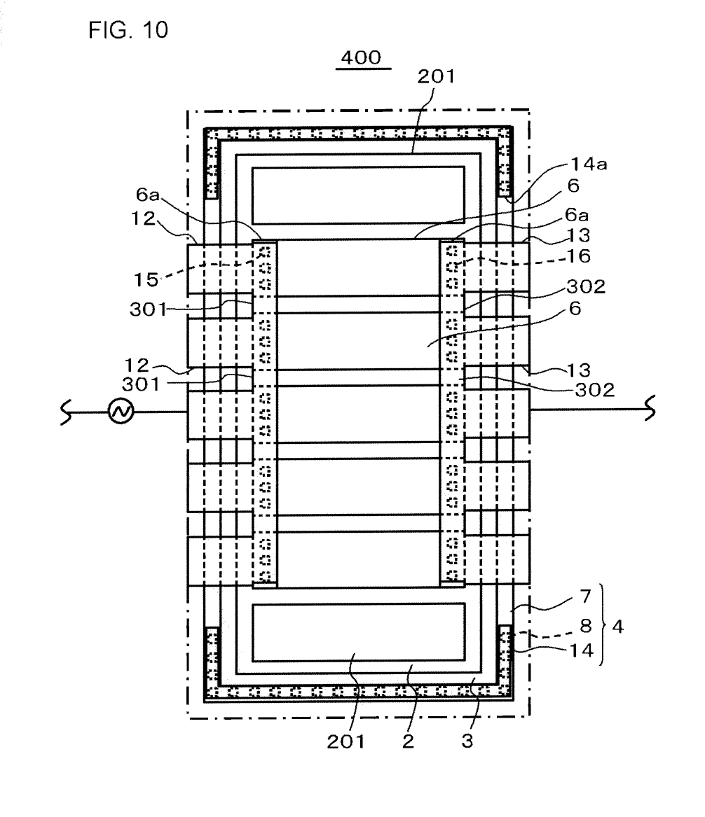

FIG. 10 is a plan view of a semiconductor device 400 according to a fourth embodiment. In FIG. 10, the interlayer insulating film 9, the interconnect layer insulating film 11, the silicide block film 17, the insulating film 5, and the insulating film 51 are not shown.

The semiconductor device 400 according to the fourth embodiment differs from the semiconductor device 300 according to the third embodiment only in the aspects described below, and the other aspects are the same as those of the semiconductor device 300.

In the above described third embodiment, the divided sections of the conductor pattern 14 are placed between the adjacent lead interconnects 12 and between the adjacent lead interconnects 13, respectively. In this embodiment, on the other hand, the divided sections of the conductor pattern 14 are not placed between the adjacent lead interconnects 12 and between the adjacent lead interconnects 13. In this embodiment, the conductor pattern 14 is divided into two sections, as in the first and second embodiments described above.

In this embodiment, the number of resistor elements 6 is five, and the number of lead interconnects 12 are five and the number of lead interconnects 13 are also five.

According to the fourth embodiment described above, the same advantageous effects as those of the second and third embodiments can be achieved.

[Fifth Embodiment]

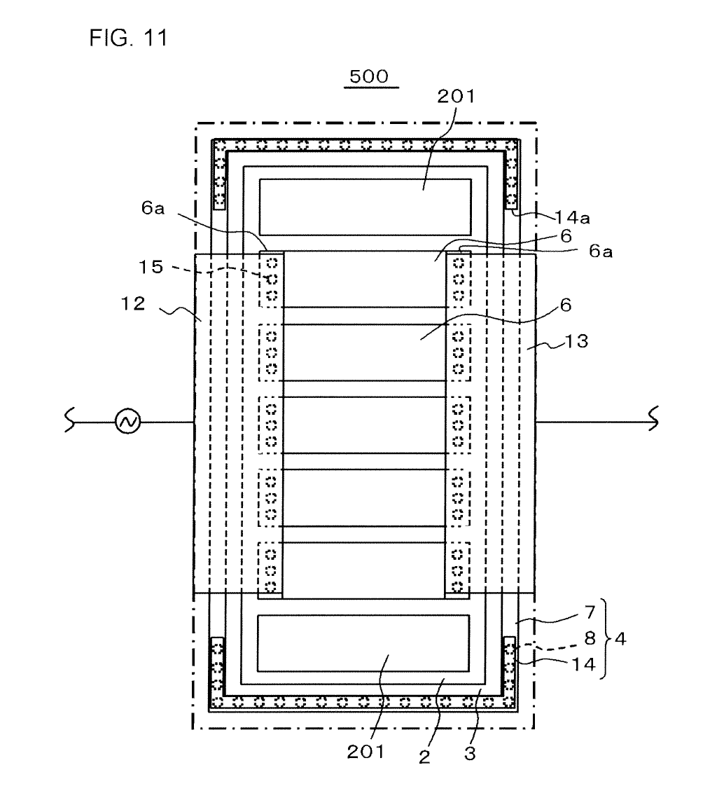

FIG. 11 is a plan view of a semiconductor device 500 according to a fifth embodiment. In FIG. 11, the interlayer insulating film 9, the interconnect layer insulating film 11, the silicide block film 17, the insulating film 5, and the insulating film 51 are not shown.

The semiconductor device 500 according to the fifth embodiment differs from the semiconductor device 400 according to the fourth embodiment only in the aspects described below, and the other aspects are the same as those of the semiconductor device 400.

In the above described fourth embodiment, the lead interconnects 12 and the lead interconnects 13 are provided for each of the resistor elements 6. In this embodiment, on the other hand, one lead interconnect 12 is connected to the respective resistor elements 6, and one lead interconnect 13 is connected to the respective resistor elements 6. The lead interconnect 12 is designed to be so wide as to cover the upper portion of one end of each of the resistor elements 6. Likewise, the lead interconnect 13 is designed to be so wide as to cover the upper portion of the other end of each of the resistor elements 6. It should be noted that, in this embodiment, the semiconductor device 500 does not include the connecting interconnects 301 and 302.

According to the fifth embodiment described above, the same advantageous effects as those of the second through fourth embodiments can be achieved.

[Sixth Embodiment]

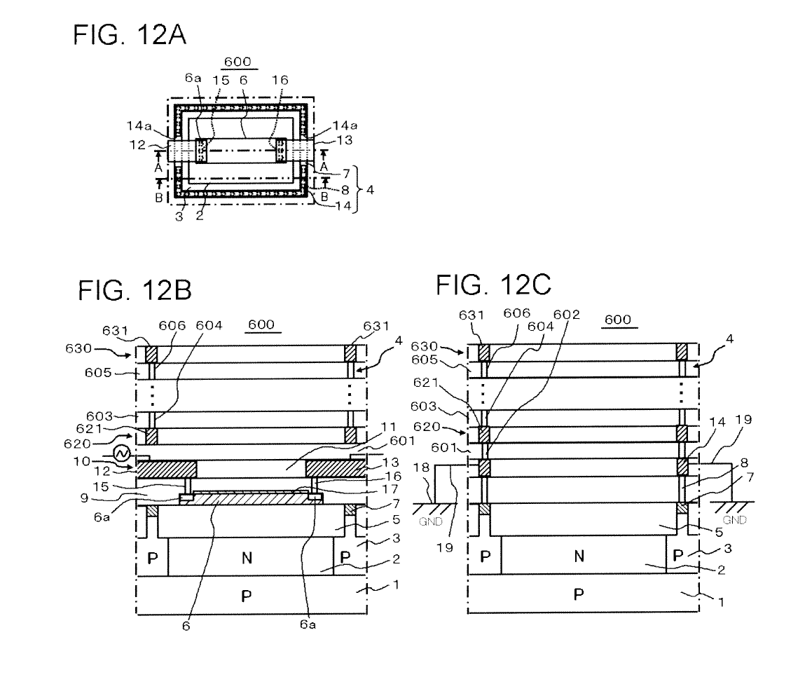

FIGS. 12A through 12C are schematic views of a semiconductor device 600 according to a sixth embodiment. FIG. 12A is a plan view of the semiconductor device 600. FIG. 12B is a cross-sectional view of the semiconductor device 600, taken along the line A-A of FIG. 12A. FIG. 12C is a cross-sectional view of the semiconductor device 600, taken along the line B-B of FIG. 12A. In FIG. 12A, the interlayer insulating film 9, the interconnect layer insulating film 11, the silicide block film 17, the insulating film 5, the insulating film 51, and the interconnect layers located on higher layer levels than the interconnect layer 10 are not shown.

In each of the above described embodiments, the guard ring 4 includes the contact plugs 8 buried in the first-layer interlayer insulating film 9, and the conductor pattern 14 of the first-layer interconnect layer 10. However, the guard ring 4 may also include a via that is buried in an interlayer insulating film located on a higher layer level than the interconnect layer 10, and a conductor pattern of an interconnect layer located on a higher layer level than the interconnect layer 10.

As shown in FIGS. 12B and 12C, a second-layer interlayer insulating film 601 is formed on the first-layer interconnect layer 10, and a second-layer interconnect layer 620 is formed on the interlayer insulating film 601. Further, interlayer insulating films and interconnect layers are alternately formed on the interconnect layer 620. In FIGS. 12B and 12C, a third-layer interlayer insulating film 603, an nth-layer (n being 4 or greater in this example) interlayer insulating film 605, and an nth-layer interconnect layer 630 are shown, but the interconnect layers and interlayer insulating films existing between the interlayer insulating film 603 and the interlayer insulating film 605 are not shown.

Vias 602 (see FIG. 12C) are formed in the second-layer interlayer insulating film 601 in positions that are located above the contact plugs 8 in an overlapping manner.

Further, vias (vias 604, 606, and the like) are formed in the third-layer interlayer insulating films and those located thereabove (the third-layer interlayer insulating film 603, the nth-layer interlayer insulating film 605, and the likes) in positions that are located above the contact plugs 8 in an overlapping manner. It should be noted that the vias in the third-layer interlayer insulating film and those located thereabove are also provided in positions that are located above and extend across the lead interconnects 12 and 13, as shown in FIG. 12B.

In the second-layer interconnect layer 620, a conductor pattern 621 is formed in a position that is located above the conductor pattern 14 in an overlapping manner. It should be noted that the planar shape of the conductor pattern 621 is the same as that of the P⁺-diffusion region 7, for example.

Further, in the third layer interconnect layer and those located thereabove (the nth-layer interconnect layer 630 and the like), conductor patterns (a conductor pattern 631 and the like) formed in positions that are located above the conductor pattern 621 in an overlapping manner. The planar shapes of those conductor patterns are also the same as that of the P⁺-diffusion region 7.

The vias and the conductor pattern of each two adjacent layers are electrically connected to each other. In this embodiment, the guard ring 4 is designed to include not only the P⁺-diffusion region 7, the contact plugs 8, and the conductor pattern 14, but also the vias and the conductor patterns ranging from the vias 602 of the second-layer interlayer insulating film 601 to the conductor pattern 631 of the nth-layer interconnect layer.

The guard ring 4 may be connected to the ground potential 18 through the interconnects of any of the interconnect layers, but is preferably connected to the ground potential 18 through the interconnects (the ground connecting lead interconnects 19) of the first-layer interconnect layer 10 to achieve preferred characteristics.

According to the sixth embodiment described above, the same advantageous effects as those of the first embodiment can be achieved.

In each of the above described embodiments, the analog element is the resistor element 6. However, the present invention is not limited to that, and another analog element such as a capacitor, a coil, an A-D converter, or an oscillator may be used in place of the resistor element 6.

Also, the conductivity type of each of the components described in the above embodiments may be reversed.

Also, in the above embodiments, instead of the contact plugs 8, conductive wall-like members may be provided, and the conductor pattern 14 and the P⁺-diffusion region 7 may be electrically connected to each other through the wall-like members. In the sixth embodiment, the same wall-like members as above may be used in place of the vias.

In the above embodiments, a guard ring formed by a single ring has been described, but the guard ring may be formed by two or more rings.

In the above embodiments, the first second-conductivity-type region positioned to cover the lower surface of the first-conductivity-type region is the semiconductor substrate 1. However, the first second-conductivity-type region may be a well region (a P-type well region, for example) formed in the semiconductor substrate 1.

It is apparent that the present invention is not limited to the above embodiments, and may he modified and changed without departing from the scope and spirit of the invention.

What is claimed is:

1. A semiconductor device comprising:
a first-conductivity-type region;
a first second-conductivity-type region that is positioned to cover a lower surface of said first-conductivity-type region;
a second second-conductivity-type region that is positioned to surround side faces of said first-conductivity-type region, and is in contact with said first second-conductivity-type region;
a guard ring that is electrically connected to said second second-conductivity-type region, and is electrically connected to a fixed potential terminal;
an insulating film that is positioned to cover an upper surface of said first-conductivity-type region; and
an analog element that is placed over said insulating film.

2. The semiconductor device according to claim 1, wherein said analog element is a resistor element.

3. The semiconductor device according to claim 2, wherein said resistor element is of a second conductivity type.

4. The semiconductor device according to claim 1, wherein, in a plan view, a visible outline of said first-conductivity-type region is located outside a visible outline of said analog element.

5. The semiconductor device according to claim 1, further comprising:
a multilayer interconnect layer that includes interlayer insulating films and interconnect layers that are alternately stacked,
wherein said guard ring includes
a high-concentration diffusion region of a second conductivity type, said high-concentration diffusion region being formed in a surface layer of said second second-conductivity-type region and surrounding said first-conductivity-type region in a ring-like manner,
a connecting member that is buried in an interlayer insulating film that is a first interlayer insulating film in said multilayer interconnect layer, and
a conductor pattern that is connected to said high-concentration diffusion region through said connecting member, said conductor pattern being formed in an interconnect layer that is a first interconnect layer in said multilayer interconnect layer.

6. The semiconductor device according to claim 5, wherein said first interconnect layer in said multilayer interconnect layer includes lead interconnects connected to said analog element, and
said conductor pattern has openings formed for allowing said lead interconnects to pass through said openings.

7. The semiconductor device according to claim 1, wherein a high-frequency signal of equal to or higher than 1 GHz in frequency is input to said analog element.

8. The semiconductor device according to claim 1, wherein said fixed potential terminal is a ground terminal.

9. A method for manufacturing a semiconductor device, comprising:
forming a first-conductivity-type region that has a lower surface covered with a first second-conductivity-type region;
forming a second second-conductivity-type region that surrounds side faces of said first-conductivity-type region, and is in contact with said first second-conductivity-type region;
forming a guard ring that is electrically connected to said second second-conductivity-type region, and is electrically connected to a fixed potential;
forming an insulating film that covers an upper surface of said first-conductivity-type region; and
forming an analog element over said insulating film.

10. The method for manufacturing a semiconductor device according to claim 9, wherein said fixed potential is a ground potential.
